(19) United States
(12) Patent Application Publication
(10) Pub. No.: US 2021/0296311 A1
(43) Pub. Date: Sep. 23, 2021

(54) SEMICONDUCTOR DEVICE AND METHOD OF MANUFACTURING SEMICONDUCTOR DEVICE

(71) Applicant: SONY SEMICONDUCTOR SOLUTIONS CORPORATION, KANAGAWA (JP)

(72) Inventors: AKITO IWAO, TOKYO (JP); YOSHIKAZU MOTOYAMA, KANAGAWA (JP)

(21) Appl. No.: 17/250,540

(22) PCT Filed: Jul. 17, 2019
(86) PCT No.: PCT/JP2019/028098

§ 371 Date: Feb. 1, 2021

(30) Foreign Application Priority Data
Aug. 9, 2018 (JP) 2018-150547

(51) Int. Cl. H01L 27/085; H01L 29/778; H01L 29/66; H01L 29/06; H01L 21/8232

(52) U.S. Cl. CPC H01L 27/085; H01L 29/7786; H01L 21/8232; H01L 29/0607; H01L 29/66462

(57) ABSTRACT

A semiconductor device including: a substrate in which a first transistor region and a second transistor region are provided; a first channel layer in which a carrier of a first conductivity type travels, the first channel layer being provided over the substrate in the first transistor region and including a compound semiconductor; a first impurity epitaxial layer of a second conductivity type that is provided over the substrate with the first channel layer interposed therebetween, is disposed in a first gate region in a central portion and outside the first gate region, and has a low concentration region in which an electric charge amount per unit length is small as compared to the first gate region; and a second channel layer in which a carrier of the second conductivity type travels, the second channel layer being provided over the substrate in the second transistor region and including a compound semiconductor.

### TECHNICAL FIELD

The present technology relates to a semiconductor device including a channel layer that includes a compound semiconductor, and a method of manufacturing the semiconductor device.

### BACKGROUND ART

A field effect transistor (FET) including a channel layer that includes a compound semiconductor has recently been developed. For example, a pseudomorphic high electron mobility transistor (pHEMT) is expected to be applied to a switching element (see, for example, PTL 1)

### CITATION LIST

### Patent Literature

PTL 1: Japanese Unexamined Patent Application Publication No. 2014-239201

### SUMMARY OF THE INVENTION

In such a semiconductor device, it is desired to provide a p-type FET and an n-type FET on one substrate.

Accordingly, it is desirable to provide a semiconductor device that is able to be provided with a p-type FET and an n-type FET on one substrate and a method of manufacturing the semiconductor device.

A semiconductor device according to an embodiment of the present technology includes: a substrate in which a first transistor region and a second transistor region are provided; a first channel layer in which a carrier of a first conductivity type travels, the first channel layer being provided over the substrate in the first transistor region and including a compound semiconductor; a first impurity epitaxial layer of a second conductivity type that is provided over the substrate with the first channel layer interposed therebetween, is disposed in a first gate region in a central portion and outside the first gate region, and has a low concentration region in which an electric charge amount per unit length is small as compared to the first gate region; and a second channel layer in which a carrier of the second conductivity type travels, the second channel layer being provided over the substrate in the second transistor region and including a compound semiconductor.

The semiconductor device according to an embodiment of the present technology includes, over the substrate in the first transistor region, the first channel layer in which the carrier of the first conductivity travels, and includes, over the substrate in the second transistor region, the second channel layer in which the carrier of the second conductivity type travels. Thus, for example, a p-type FET is formed over the substrate in the first transistor region and an n-type FET is formed over the substrate in the second transistor region.

A method of manufacturing a semiconductor device according to an embodiment of the present technology includes: forming, over a substrate in a first transistor region, a first channel layer in which a carrier of a first conductivity type is allowed to travel, the first channel layer including a compound semiconductor; forming a first impurity epitaxial layer of a second conductivity type at a position opposed to the substrate with the first channel layer interposed therebetween, and forming, over the substrate in a second transistor region, a second channel layer in which a carrier of the second conductivity type is allowed to travel, the second channel layer including a compound semiconductor; and forming a first gate region in a central portion of the first impurity epitaxial layer and a low concentration region outside the first gate region, by diffusing selectively an impurity of the second conductivity type in the central portion of the first impurity epitaxial layer.

The method of manufacturing the semiconductor device according to an embodiment of the present technology includes forming, over the substrate in the first transistor region, the first channel layer in which the carrier of the first conductivity travels, and forming, over the substrate in the second transistor region, the second channel layer in which the carrier of the second conductivity type travels. Thus, for example, the p-type FET is formed over the substrate in the first transistor region and the n-type FET is formed over the substrate in the second transistor region.

According to the semiconductor device and the method of manufacturing the semiconductor device of an embodiment of the present technology, the first channel layer is formed over the substrate in the first transistor region and the second channel layer is formed over the substrate in the second transistor region, which makes it possible to form the p-type FET over the substrate in the first transistor region and form the n-type FET over the substrate in the second transistor region. Thus, it is possible to provide the p-type FET and the n-type FET on one substrate.

It is to be noted that the above is an example of the present disclosure. The effect of the present disclosure is not limited to those described above, and may include other different effects or may further include other effects.

### BRIEF DESCRIPTION OF DRAWINGS

FIG. 1 is a cross-sectional schematic view of a configuration of a main part of a semiconductor device according to a first embodiment of the present technology.

FIG. 2A is a cross-sectional schematic view of a process of manufacturing the semiconductor device illustrated in FIG. 1.

FIG. 2B is a cross-sectional schematic view of a process following FIG. 2A.

FIG. 2C is a cross-sectional schematic view of a process following FIG. 2B.

FIG. 2D is a cross-sectional schematic view of a process following FIG. 2C.

FIG. 3A is a cross-sectional schematic view of a process following FIG. 2D.

FIG. 3B is a cross-sectional schematic view of a process following FIG. 3A.

FIG. 3C is a cross-sectional schematic view of a process following FIG. 3B.

FIG. 4A is a cross-sectional schematic view of a process following FIG. 3C.

FIG. 4B is a cross-sectional schematic view of a process following FIG. 4A.

FIG. 4C is a cross-sectional schematic view of a process following FIG. 4B.

FIG. 5A is a diagram illustrating an example of Vg-Id characteristics and Vg-Ig characteristics of a p-type FET formed in a second transistor region illustrated in FIG. 1.

FIG. 5B is a diagram illustrating another example of the Vg-Id characteristics and the Vg-Ig characteristics illustrated in FIG. 5A.

FIG. 6 is a cross-sectional schematic view of a configuration of a main part of a semiconductor device according to a comparative example.

FIG. 7 is a cross-sectional schematic view of a configuration of a main part of a semiconductor device according to a modification example.

### MODES FOR CARRYING OUT THE INVENTION

In the following, some embodiments of the present disclosure are described in detail with reference to the drawings. It is to be noted that description is given in the following order.

### 1. Embodiment

A semiconductor device including an n-type FET in a first transistor region, an p-type FET in a second transistor region, and the n-type FET in a third transistor region

### 2. Modification Example

An example in which the n-type FETs provided in the first transistor region and the third transistor region are each an n-type FET of a depletion type

### Embodiment

### (Configuration of Semiconductor Device 1)

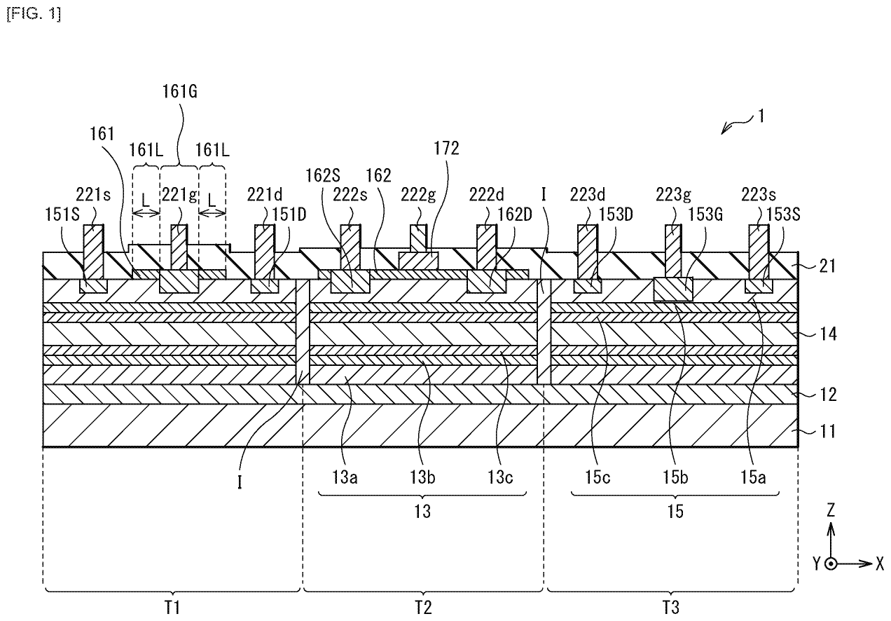

FIG. 1 is a cross-sectional diagram illustrating a main configuration of a semiconductor device (a semiconductor device 1) according to an embodiment to which the present technology is applied. It is to be noted that the description will be made with an assumption that a first conductivity type of the present technology is an n-type and a second conductivity type of the present technology is a p-type, and this may also be reversed.

The semiconductor device 1 includes a buffer layer 12, a lower barrier layer 13, a channel layer 14 (a first channel layer), an upper barrier layer 15, and an interlayer insulating film 21 in this order over a substrate 11. The substrate 11 is provided with a first transistor region T1, a second transistor region T2, and a third transistor region T3. The buffer layer 12, the lower barrier layer 13, the channel layer 14, the upper barrier layer 15, and the interlayer insulating film 21 are provided over the substrate 11 across the first transistor region T1, the second transistor region T2, and the third transistor region T3. The lower barrier layer 13, the channel layer 14, and the upper barrier layer 15 have an element separation region I at each of boundaries of the first transistor region T1, the second transistor region T2, and the third transistor region T3.

The semiconductor device 1 includes: a p-type impurity epitaxial layer 161 (a first impurity epitaxial layer) on the upper barrier layer 15 in the first transistor region T1; and a channel layer 162 (a second channel layer) and an n-type impurity epitaxial layer 172 (a second impurity epitaxial layer) over the upper barrier layer 15 in the second transistor region T2. In the first transistor region T1, a gate electrode 221g is provided on the p-type impurity epitaxial layer 161, and a pair including a source electrode 221s and a drain electrode 221d is provided on the upper barrier layer 15. In the second transistor region T2, a gate electrode 222g is provided on the n-type impurity epitaxial layer 172, and a pair including a source electrode 222s and a drain electrode 222d is provided on the channel layer 162. In the third transistor region T3, a gate electrode 223g and a pair including a source electrode 223s and a drain electrode 223d are each provided on the upper barrier layer 15.

### [Substrate 11]

The substrate 11 includes a semi-insulating compound semiconductor material. Such a substrate 11 includes, for example, a group III-V compound semiconductor material, and, for example, a semi-insulating single-crystal GaAs substrate or InP substrate is used.

### [Buffer Layer 12]

The buffer layer 12 includes a compound semiconductor layers epitaxially grown on the substrate 11, for example, and includes a compound semiconductor that is well lattice-matched to the substrate 11 and the lower barrier layer 13. For example, in a case where the substrate 11 includes the single-crystal GaAs substrate, as an example of such a buffer layer 12, an epitaxially grown layer of i-GaAs to which no impurity is added (i—indicates that no impurity is added; hereinafter, the same) is used.

### [Lower Barrier Layer 13]

The lower barrier layer 13 provided between the buffer layer 12 and the channel layer 14 includes, for example, a group III-V compound semiconductor which is well lattice-matched to the buffer layer 12 and the channel layer 14, and has a wide band gap as compared to a compound semiconductor material included in the channel layer 14. As an example of such a lower barrier layer 13, there is given an epitaxially grown layer of an AlGaAs mixed crystal is used. Here, in particular, it is assumed that the lower barrier layer 13 includes an Al_{0.2}Ga_{0.8}As mixed crystal in which a composition ratio of aluminum (Al) in the group III elements is, for example, 0.2; however, the composition ratio of the aluminum is not limited thereto.

Such a lower barrier layer 13 includes a carrier supply region 13b containing impurities which supply carriers. Here, it is assumed that an electron is used as the carrier, and the n-type carrier supply region 13b containing n-type impurities as impurities for supplying electrons is disposed in an intermediate portion in a film thickness direction (Z direction in FIG. 1) of the lower barrier layer 13. As an n-type impurity contained in the lower barrier layer 13 including the Al_{0.2}Ga_{0.8}As mixed crystal, there is given silicon (Si). The concentration of the n-type impurities in the carrier supply region 13b is, for example, 4.0×10¹⁸ to 8.0×10¹⁸ atoms/cm³. The carrier supply region 13b has a thickness of, for example, about 3 nm.

High-resistance regions 13a and 13c are provided in a film thickness portion of the lower barrier layer 13 excluding a portion of the carrier supply region 13b. For example, the high-resistance region 13a is provided between the buffer layer 12 and the carrier supply region 13b, and the high-resistance region 13c is provided between the carrier supply region 13b and the channel layer 14. The high-resistance regions 13a and 13c are for forming a satisfactory heterojunction interface with the buffer layer 12 and the channel layer 14, and each include, for example, an i-AlGaAs mixed crystal to which no impurity is added. The high-resistance regions 13a and 13c may contain low-concentration n-type impurities or p-type impurities. The high-resistance region 13a has a thickness of, for example, about 20 nm, and the high-resistance region 13c has a thickness of, for example, about 3 nm. The lower barrier layer 13 may not necessarily include the high-resistance regions 13a and 13c, and an entire region of the lower barrier layer 13 may include the carrier supply region 13b.

### [Channel Layer 14]

The channel layer 14 functions as a current path between the pair of source/drain electrodes 221s and 221d in the first transistor region T1 and the pair of source/drain electrodes 223s and 223d in the third transistor region T3. The channel layer 14 is a layer in which carriers supplied from the carrier supply region 13b of the lower barrier layer 13 and from a carrier supply region 15b of the upper barrier layer 15 to be described later are accumulated. Such a channel layer 14 includes a compound semiconductor heterojunction to the lower barrier layer 13 and is well lattice-matched to the lower barrier layer 13. Further, it is assumed that the channel layer 14 includes a compound semiconductor whose energy band on a carrier traveling side at the heterojunction with the lower barrier layer 13 is closer to the intrinsic Fermi level in the channel layer than an energy band on a carrier traveling side in a compound semiconductor material included in an interface region of the lower barrier layer 13. Thus, the lower barrier layer 13 includes a compound semiconductor whose energy band on a carrier traveling side at the junction with the channel layer 14 is far from the intrinsic Fermi level in the channel layer as compared to the channel layer 14.

In other words, it is assumed that the channel layer 14 includes a compound semiconductor whose energy band on a majority carrier traveling side at the heterojunction with the lower barrier layer 13 is closer to an energy band on a minor carrier traveling side than an energy band on a majority carrier traveling side in the compound semiconductor material included in the interface region of the lower barrier layer 13. The intrinsic Fermi level in the channel layer is located in the middle between the lowest energy of a conduction band of the channel layer 14 (hereinafter referred to as conduction band energy Ec) and the highest energy of a valence band (hereinafter referred to as valence band energy Ev).

Here, if the carriers are electrons, the energy band on the carrier traveling side is a conduction band. For this reason, the channel layer 14 includes a group III-V compound semiconductor material having at least a conduction band energy Ec lower than that of the compound semiconductor material included in the lower barrier layer 13 at the junction with the lower barrier layer 13. Such a channel layer 14 is more desirable if the difference in the conduction band energy Ec with respect to the lower barrier layer 13 at the junction with the lower barrier layer 13 is greater.

In contrast, in a case where the carriers are holes, the energy band on carrier traveling side is a valence band. For this reason, the channel layer 14 includes a compound semiconductor material having at least a valence band energy Ev higher than that of the compound semiconductor material included in the lower barrier layer 13 at the junction with the lower barrier layer 13. Such a channel layer 14 is more desirable if the difference in the valence band energy Ev with the lower barrier layer 13 at the junction with the lower barrier layer 13 is greater. In the following, the case where the carriers are electrons is illustrated and described. In the case where the carriers are holes, the description of the impurities and the energy band may each have a reverse conductivity type.

Such a channel layer 14 includes a group III-V compound semiconductor material that is well lattice-matched to the lower barrier layer 13 and has a narrower band gap than the compound semiconductor material included in the lower barrier layer 13. Further, such a channel layer 14 is more desirable if the difference in the band gap with the lower barrier layer 13 is greater.

The channel layer 14 as described above includes, for example, an InGaAs mixed crystal, in a case where the lower barrier layer 13 includes the Al_{0.2}Ga_{0.8}As mixed crystal. In this case, the increase in a composition ratio of indium (In) makes it possible to narrow the band gap in the InGaAs mixed crystal, and to increase the difference in the conductance band energy Ec with the lower barrier layer 13 including the AlGaAs mixed crystal. Therefore, in the InGaAs mixed crystal included in the channel layer 14, the composition ratio of indium (In) in the group III elements may be 0.1 or more.

An example of the channel layer 14 described above includes an In_{0.2}Ga_{0.8}As mixed crystal in which composition ratio of indium (In) in the group III elements is 0.2. Thus, the channel layer 14 obtains a sufficient difference in the conduction band energy Ec while ensuring the lattice matching to the lower barrier layer 13. It is to be noted that the composition ratio of indium is not limited to the above examples.

The channel layer 14 includes, for example, an i-InGaAs mixed crystal layer to which no impurity is added. This suppresses impurity-scattering of the carriers in the channel layer 14 and achieves carrier transfer with high mobility.

The channel layer 14 is, for example, an epitaxially grown layer having a thickness of 5 nm to 10 nm or less. The channel layer 14 is thus a layer that ensures crystallinity and has an excellent carrier traveling property.

A GaAs-based compound semiconductor material has, for example, a band gap of about 1.4 eV, a critical strength of about 0.4 MV/cm, and an electron mobility of about 8500 cm²/Vs. Such a GaAs-based compound semiconductor material having high electron mobility is suitably used for a high-frequency switching application.

### [Upper Barrier Layer 15]

The upper barrier layer 15 is well lattice-matched to the channel layer 14. The upper barrier layer 15 includes a compound semiconductor in which an energy band on a carrier traveling side is farther from the intrinsic Fermi level in the channel layer than an energy band of the compound semiconductor material included in the channel layer 14 at the junction with the channel layer 14. That is, it is assumed that the upper barrier layer 15 includes a compound semiconductor in which an energy band on a majority carrier traveling side is farther from the intrinsic Fermi level in the channel layer than the energy band of the compound semiconductor material included in the channel layer 14 at the junction with the channel layer 14. If the carriers are electrons, the upper barrier layer 15 includes a group Ill-V compound semiconductor material having a conduction band energy Ec higher than that of the compound semiconductor material included in the channel layer 14. Such an upper barrier layer 15 is more desirable if the difference in the conduction band energy Ec with the channel layer 14 at the junction with the channel layer 14 is greater.

The upper barrier layer 15 as described above includes, for example, an AlGaAs mixed crystal having a band gap wider than that of the InGaAs mixed crystal, for example, if the channel layer 14 includes the InGaAs mixed crystal. In this case, keeping a low composition ratio of aluminum (Al) makes it possible to prevent a so-called source resistance from increasing. For this reason, the composition ratio of aluminum (Al) in the group III elements may be 0.25 or less in the AlGaAs mixed crystal included in the upper barrier layer 15.

An example of the upper barrier layer 15 described above includes an Al_{0.2}Ga_{0.8}As mixed crystal in which composition ratio of aluminum (Al) in the group III elements is 0.2. This also ensures the lattice-matching with the channel layer 14. The upper barrier layer 15 does not necessarily have the same composition as that of the lower barrier layer 13, and may include an AlGaAs mixed crystal having a composition suitable for the individual, and the composition ratio is not limited to the above examples.

Such an upper barrier layer 15 has a carrier supply region 15b containing impurities which supply carriers. The carrier supply region 15b contains, for example, silicon (Si) as an n-type impurity that supplies an electron. The concentration of the n-type impurities in the carrier supply region 15b is, for example, 1.0×10¹⁸ to 4.0×10¹⁸ atoms/cm³. The n-type carrier supply region 15b is disposed in an intermediate portion in a film thickness direction of the upper barrier layer 15, and has a thickness of, for example, about 6 nm.

The upper barrier layer 15 includes high-resistance regions 15a and 15c that sandwich the carrier supply region 15b in the film thickness direction. For example, the high-resistance region 15a is provided between the carrier supply region 15b and the interlayer insulating film 21, and the high-resistance region 15c is provided between the channel layer 14 and the carrier supply region 15b. The high-resistance region 15a contains, for example, silicon (Si) as an n-type impurity. The concentration of the n-type impurities in the high-resistance region 15a is, for example, 1.0×10¹⁶ to 4.0×10¹⁶ atoms/cm³. The high-resistance region 15c is for forming a satisfactory heterojunction interface with the channel layer 14, and includes, for example, an i-AlGaAs mixed crystal to which no impurity is added. The high-resistance region 15a has a thickness of, for example, about 50 nm to 100 nm, and the high-resistance region 15c has a thickness of, for example, about 3 nm.

In a case where the channel layer 14 includes the InGaAs mixed crystal, the upper barrier layer 15 is not limited to the AlGaAs mixed crystal, and may include an In(AlGa)AsP mixed crystal that is a group III-V compound semiconductor. As a result, it is possible to increase the composition ratio of In in the channel layer 14 including the InGaAs mixed crystal, and to increase carrier mobility in the channel layer 14.

### [Element Separation Region I]

The first transistor region T1, the second transistor region T2, and the third transistor region T3 are insulated from each other by element separation regions I provided on the lower barrier layer 13, the channel layer 14, and the upper barrier layer 15. The element separation region I is, for example, an inactive region which is made highly resistive by ion implantation of boron (B) or the like. In FIG. 1, one element separation region I is provided between the first transistor region T1 and the second transistor region T2, and another element separation region I is provided between the second transistor region T2 and the third transistor region T3. In addition to the example illustrated in FIG. 1, in a region where there is no second transistor region T2 and the first transistor region T1 and the third transistor region T3 are adjacent, the element separation region I may be provided between the first transistor region T1 and the third transistor region T3.

### [Interlayer Insulating Film 21]

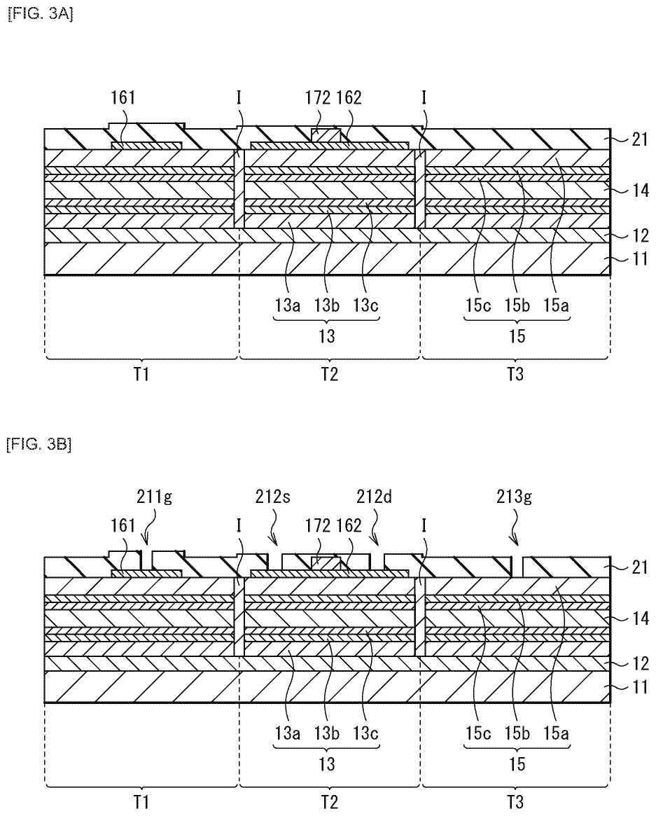

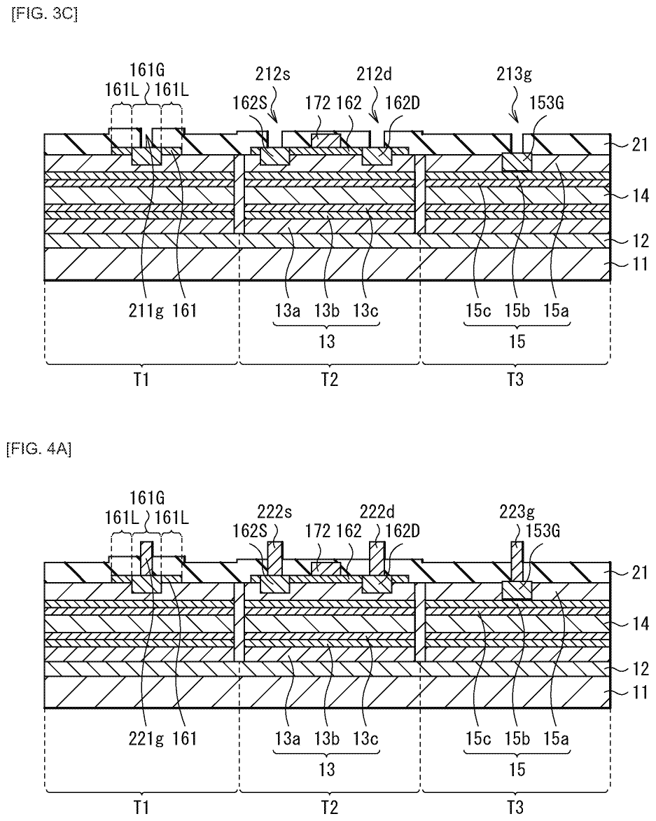

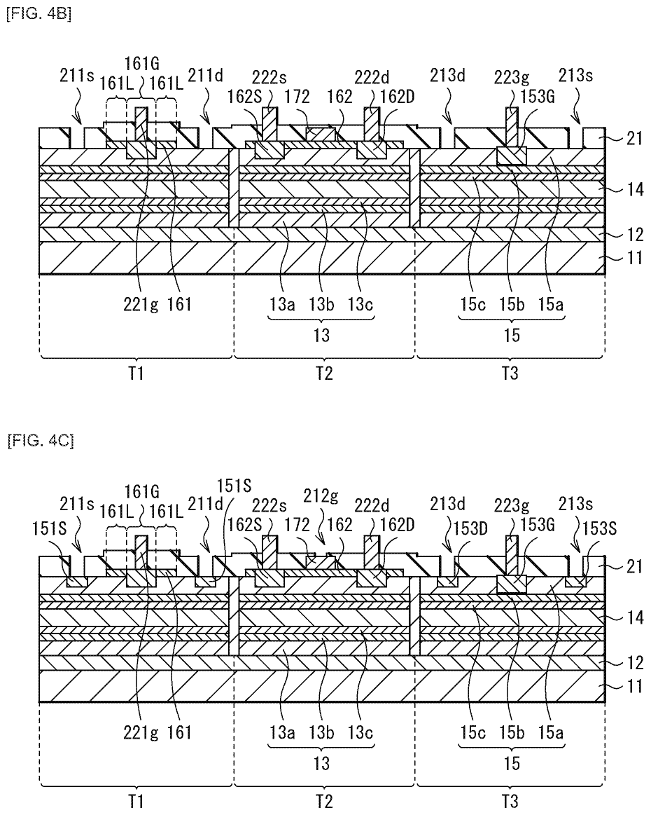

The interlayer insulating film 21 is provided to cover the entire surface of the upper barrier layer 15. The interlayer insulating film 21 includes a material having an insulating property with respect to the compound semiconductor included in the upper barrier layer 15 and having a function of protecting a surface of the upper barrier layer 15 from impurities such as ions. Such an interlayer insulating film 21 includes, for example, silicon nitride (Si₃N₄) having a thickness of 200 nm. The interlayer insulating film 21 has openings for providing gate electrodes 221g, 222g, and 223g, source electrodes 221s, 222s, and 223s, and drain electrodes 221d, 222d, and 223d (see FIGS. 3B, 3C, 4B, and 4C to be described later).

The buffer layer 12, the lower barrier layer 13, the channel layer 14, the upper barrier layer 15, and the interlayer insulating film 21 described above are commonly provided over the substrate 11 for the first transistor region T1, the second transistor region T2, and the third transistor region T3. Hereinafter, structures of the first transistor region T1, the second transistor region T2, and the third transistor region T3 will be described. First, the structure of the first transistor region T1 on the substrate 11 will be described.

### [P-Type Impurity Epitaxial Layer 161]

The p-type impurity epitaxial layer 161 is provided over the substrate 11 in the first transistor region T1. The p-type impurity epitaxial layer 161 is provided on a selective region on the upper barrier layer 15. In other words, the p-type impurity epitaxial layer 161 is provided over the substrate 11 with the channel layer 14 interposed therebetween. The p-type impurity epitaxial layer 161 includes, for example, a group III-V compound semiconductor which is well lattice-matched to the upper barrier layer 15. Specifically, the p-type impurity epitaxial layer 161 includes an AlGaAs mixed crystal containing carbon (C) as a p-type impurity. The concentration of the p-type impurities contained in the p-type impurity epitaxial layer 161 is, for example, about 1.0×10¹⁸ atoms/cm³. The p-type impurity epitaxial layer 161 may contain zinc (Zn), magnesium (Mg), or the like as a p-type impurity.

The p-type impurity epitaxial layer 161 is provided with a gate region 161G (a first gate region) and low concentration regions 161L. The gate region 161G is disposed on a central portion of the p-type impurity epitaxial layer 161 in a plan view (XY plane in FIG. 1). This gate region 161G is a region that contains impurities of the conductivity type reverse to that of the carriers traveling in the channel layer 14 in the first transistor region T1, and is provided from the p-type impurity epitaxial layer 161 into a portion in the thickness direction of the high-resistance region 15a. The gate region 161G is kept at a lower resistance than the surrounding high-resistance region 15a. For example, in a case where the carriers are electrons, zinc (Zn), for example, is diffused as a p-type impurity into the gate region 161G. The gate region 161G contains, for example, p-type impurities of about 1×10¹⁹ atoms/cm³.

The low concentration regions 161L are provided on outer sides of the gate region 161G. The low concentration regions 161L are each a region of the p-type impurity epitaxial layer 161 other than the gate region 161G, and are provided on both sides (a source electrode 221s side and a drain electrode 221d side) of the gate region 161G continuously to the gate region 161G. In the low concentration regions 161L, a p-type electric charge amount of the entire regions is smaller than that of the gate region 161G. The p-type electric charge amount in the low concentration regions 161L is a degree to which holes (electric charges having the conductivity type reverse to that of the carriers traveling in the channel layer 14) in the low concentration region 161L are depleted during off-operation when a negative voltage is applied to the gate electrode 221g. In the first transistor region T1, the provision of such low concentration regions 161L makes it possible to spread a depletion layer in lower layers of the low concentration regions 161L, and to increase pressure resistance between the gate and the drain (see PTL 1).

It is preferred that the low concentration regions 161L each have small electric charge amount per unit length of the p-type (per unit horizontal-direction length in FIG. 1) as compared to the gate region 161G. This allows the low concentration regions 161L to each have a small electric charge amount of the p-type as compared to the gate region 161G, even if the horizontal-direction lengths of the low concentration regions 161L become extremely large.

Here, in particular, it is assumed that the low concentration regions 161L are shallower than the gate region 161G, that is, smaller in thickness than the gate region 161G. Thus, it is assumed that the electric charge amount of the p-type in the low concentration regions 161L is kept small as compared to the gate region 161G. In this case, for example, the p-type impurity concentration of the low concentration region 161L is the same as the p-type impurity concentration of the p-type impurity epitaxial layer 161, and is about 1×10¹⁸ atoms/cm³.

The depth (the film thickness) of each low concentration region 161L may be about the same depth (the film thickness) as the gate region 161G. In this case, the p-type impurity concentration of the low concentration regions 161L is further lower than the p-type impurity concentration of the gate region 161G.

Distances L of the respective low concentration regions 161L are sufficiently large, for example, so long as the low concentration regions 161L do not reach the source electrode 221s and the drain electrode 221d. Each distance L of the low concentration region 161L is a width of an overhang from the gate region 161G, and is a distance from an end on the gate region 161G side to an end surface of the p-type impurity epitaxial layer 161. The distance L is, for example, about 0.5 μm. The distance L is determined by an operating voltage, and the distance L on the source electrode 221s side may be different from the distance L on the drain electrode 221d side.

[Gate Electrode 221g]

The gate electrode 221g is provided on the p-type impurity epitaxial layer 161, and is selectively disposed at a position overlapped with the gate region 161G in a plan view. The gate electrode 221g is provided so as to fill an opening provided in the interlayer insulating film 21, and a lower surface of the gate electrode 221g is in contact with the gate region 161G. The gate electrode 221g includes, for example, a stacked film in which titanium (Ti) and gold (Au) are stacked in this order from the substrate 11 side. The gate electrode 221g may include a stacked film in which titanium (Ti), platinum (Pt), and gold (Au) are stacked in this order from the substrate 11 side.

### [Source Region 151S/Drain Region 151D]

In a plan view, a source region 151S and a drain region 151D are provided at positions away from the p-type impurity epitaxial layer 161. The source region 151S and the drain region 151D are disposed with the p-type impurity epitaxial layer 161 interposed therebetween. The source region 151S and the drain region 151D are each an n-type ohmic contact metal diffusion layer formed over a portion in a thickness direction of the high-resistance region 15a from a surface of the high-resistance region 15a (a surface on the interlayer insulating film 21 side). For example, the n-type ohmic contact metal diffusion layer is formed by stacking 50 nm each of gold-germanium (Au—Ge), nickel (Ni), and gold (Au) in this order from the upper barrier layer 15 side, and thermally diffusing the resultant at a temperature of about 500° C.

[Source Electrode 221s/Drain Electrode 221d]

The source electrode 221s and the drain electrode 221d are provided on the upper barrier layer 15 and are disposed at positions sandwiching the gate electrode 221g and the p-type impurity epitaxial layer 161. The source electrode 221s and the drain electrode 221d are provided so as to fill openings provided in the interlayer insulating film 21. The source electrode 221s is disposed at a position overlapped with the source region 151S in a plan view, and a lower surface of the source electrode 221s is in contact with the source region 151S. The drain electrode 221d is disposed at a position overlapped with the drain region 151D in a plan view, and a lower surface of the drain electrode 221d is in contact with the drain region 151D. The source electrode 221s is ohmically bonded to the source region 151S, and the drain electrode 221d is ohmically bonded to the drain region 151D. The source electrode 221s and the drain electrode 221d are each formed by stacking titanium (Ti), titanium nitride (TiN), titanium (Ti), and copper (Cu) in this order from the upper barrier layer 15 side, and alloyed with an underlying n-type ohmic contact metal diffusion layer (the source region 151S or the drain region 151D). The source electrode 221s and the drain electrode 221d each have a thickness of, for example, 300 nm. The thicknesses of the source electrode 221s and the drain electrode 221d are not limited to the above example.

In the first transistor region T1, an n-type FET having such a configuration is formed. The n-type FET includes the p-type impurity epitaxial layer 161 and the gate electrode 221g in this order on the surface of the upper barrier layer 15. That is, the n-type FET formed in the first transistor region T1 has a pHEMT structure.

Next, a structure of the second transistor region T2 on the substrate 11 will be described.

### [Channel Layer 162]

The channel layer 162 is provided over the substrate 11 in the second transistor region T2. The channel layer 162 functions as a current path between the pair of source/drain electrodes 222s and 222d provided in the second transistor region T2. Carriers traveling in the channel layer 162 each have a conductivity type reverse to that of carriers traveling in the channel layer 14 in the first transistor region T1. For example, in a case where the carriers traveling in the channel layer 14 in the first transistor region T1 are electrons, the carriers traveling in the channel layer 162 are holes. In the present embodiment, a p-type FET is formed by providing such a channel layer 162 in the second transistor region T2. Thus, it is possible to form the p-type FET over the substrate 11 in the second transistor region together with the n-type FET in the first transistor region T1.

The channel layer 162 is provided in a selective region on the upper barrier layer 15. The channel layer 162 is formed, for example, in the same process as the p-type impurity epitaxial layer 161 in the first transistor region T1, includes the same compound semiconductor material as the material included in the p-type impurity epitaxial layer 161, and has a thickness that is substantially the same as the thickness of the p-type impurity epitaxial layer 161. That is, the channel layer 162 is provided in the same layer as the p-type impurity epitaxial layer 161. For example, the channel layer 162 includes an AlGaAs mixed crystal containing carbon (C) as a p-type impurity. The concentration of the p-type impurities contained in the channel layer 162 is substantially the same as the concentration of the p-type impurities in the p-type impurity epitaxial layer 161, and is, for example, about 1.0×10¹⁸ atoms/cm³. The concentration of the p-type impurities contained in the channel layer 162 is not limited to this example.

### [N-type Impurity Epitaxial Layer 172]

The n-type impurity epitaxial layer 172 is provided in a selective region on the channel layer 162. The n-type impurity epitaxial layer 172 is disposed on a central portion of the channel layer 162 in a plan view. The n-type impurity epitaxial layer 172 includes, for example, GaAs containing silicon (Si) as an n-type impurity. The n-type impurity epitaxial layer 172 contains silicon (Si) as a n-type impurity at a concentration of, for example, 1×10¹⁷ to 5×10¹⁹ atoms/cm³. The n-type impurity epitaxial layer 172 has a thickness of, for example, about 10 nm to 50 nm. The n-type impurity epitaxial layer 172 functions as a gate region in the second transistor region T2.

### [Source Region 162S/Drain Region 162D]

In a plan view, a source region 162S and a drain region 162D are provided at positions away from the n-type impurity epitaxial layer 172. The source region 162S and the drain region 162D are disposed with the n-type impurity epitaxial layer 172 interposed therebetween. The source region 162S and the drain region 162D are each a region in which p-type impurities are diffused over a portion in a thickness direction of the high-resistance region 15a from a surface of the channel layer 162 (a surface opposite to a surface on the upper barrier layer 15 surface side). The source region 162S and the drain region 162D are each formed, for example, in the same process as the gate region 161G in the first transistor region T1, and contain the same p-type impurities as the p-type impurities contained in the gate region 161G at a concentration that is substantially the same as the impurity concentration of the gate region 161G. For example, the source region 162S and the drain region 162D each have a thickness that is substantially the same as the thickness of the gate region 161G. Zinc (Zn), for example, is diffused into the source region 162S and the drain region 162D as a p-type impurity. The source region 162S and the drain region 162D each contain p-type impurities of about 1×10¹⁹ atoms/cm³.

[Source Electrode 222s/Drain Electrode 222d]

The source electrode 222s and the drain electrode 222d are provided on the channel layer 162 and are disposed at positions sandwiching the n-type impurity epitaxial layer 172. The source electrode 222s and the drain electrode 222d are provided so as to fill openings provided in the interlayer insulating film 21. The source electrode 222s is disposed at a position overlapped with the source region 162S in a plan view, and a lower surface of the source electrode 222s is in contact with the source region 162S. The drain electrode 222d is disposed at a position overlapped with the drain region 162D in a plan view, and a lower surface of the drain electrode 222d is in contact with the drain region 162D. The source electrode 222s is ohmically bonded to the source region 162S, and the drain electrode 222d is ohmically bonded to the drain region 162D. The source electrode 222s and the drain electrode 222d are formed, for example, in the same process as the gate electrode 221g in the first transistor region T1, include the same material as the material included in the gate electrode 221g, and each have a thickness that is substantially the same as the thickness of the gate electrode 221g.

[Gate Electrode 222g]

The gate electrode 222g is provided on a selective region on the n-type impurity epitaxial layer 172. The gate electrode 222g is provided so as to fill an opening provided in the interlayer insulating film 21, and a lower surface of the gate electrode 222g is in contact with the n-type impurity epitaxial layer 172. The gate electrode 222g is formed, for example, in the same process as the source electrode 221s and the drain electrode 221d in the first transistor region T1, includes the same material included in the source electrode 221s and the drain electrode 221d, and has a thickness that is substantially the same as the thicknesses of the source electrode 221s and the drain electrode 221d.

Subsequently, a structure of the third transistor region T3 on the substrate 11 will be described. The structure of the third transistor region T3 is similar to the structure of the first transistor region T1; however, the third transistor region T3 is not provided with a layer corresponding to the p-type impurity epitaxial layer 161 in the first transistor region T1.

### [Gate Region 153G]

A gate region 153G (a second gate region) is provided over the substrate 11 in the third transistor region T3. The gate region 153G is a region that contains impurities of the conductivity type reverse to that of the carriers traveling in the channel layer 14 in the third transistor region T3, and is provided from a surface of the high-resistance region 15a into a portion in the thickness direction of the high-resistance region 15a. The gate region 153G is kept at a lower resistance than the surrounding high-resistance region 15a. The gate region 153G is formed, for example, in the same process as the gate region 161G in the first transistor region T1, and contains the same impurities as the impurities contained in the gate region 161G at a concentration that is substantially the same as the impurity concentration of the gate region 161G. For example, the gate region 153G has a thickness that is substantially the same as the thickness of the gate region 161G. As described above, the third transistor region T3 is not provided with a layer corresponding to the p-type impurity epitaxial layer 161 in the first transistor region T1; thus, the thickness of the gate region 153G occupied in the high-resistance region 15a is larger than the thickness of the gate region 161G occupied in the high-resistance region 15a. That is, a distance between the channel layer 14 and the gate region 153G in the third transistor region T3 is shorter than a distance between the channel layer 14 and the gate region 161G in the first transistor region T1. For example, in a case where the carriers are electrons, zinc (Zn), for example, is diffused as a p-type impurity into the gate region 153G. The gate region 153G contains, for example, p-type impurities of about 1×10¹⁹ atoms/cm³.

[Gate Electrode 223g]

The gate electrode 223g is provided on the upper barrier layer 15, and is selectively disposed at a position overlapped with the gate region 153G in a plan view. The gate electrode 223g is provided so as to fill an opening provided in the interlayer insulating film 21, and a lower surface of the gate electrode 223g is in contact with the gate region 153G. The gate electrode 223g is formed, for example, in the same process as the gate electrode 221g in the first transistor region T1, includes the same material as the material included in the gate electrode 221g, and has a thickness that is substantially the same as the thickness of the gate electrode 221g.

### [Source Region 153S/Drain Region 153D]

In a plan view, a source region 153S and a drain region 153D are provided at positions away from the gate region 153G. The source region 153S and the drain region 153D are disposed with the gate region 153G interposed therebetween. The source region 153S and the drain region 153D are each a region in which an n-type ohmic metal is thermally diffused over a portion in a thickness of the high-resistance region 15a from a surface of the high-resistance region 15a (a surface on the interlayer insulating film 21 side). For example, the source region 153S and the drain region 153D are formed in the same process as the source region 151S and the drain region 151D in the first transistor region T1, and contain the same impurities as the impurities contained in the source region 151S and the drain region 151D at a concentration substantially the same as the impurity concentration of the source region 151S and the drain region 151D. For example, the source region 153S and the drain region 153D each have a thickness that is substantially the same as the thicknesses of the source region 151S and the drain region 151D.

[Source Electrode 223s/Drain Electrode 223d]

The source electrode 223s and the drain electrode 223d are provided on the upper barrier layer 15 and are disposed at positions sandwiching the gate electrode 223g. The source electrode 223s and the drain electrode 223d are provided so as to fill openings provided in the interlayer insulating film 21. The source electrode 223s is disposed at a position overlapped with the source region 153S in a plan view, and a lower surface of the source electrode 223s is in contact with the source region 153S. The drain electrode 223d is disposed at a position overlapped with the drain region 153D in a plan view, and a lower surface of the drain electrode 223d is in contact with the drain region 153D. The source electrode 223s is ohmically bonded to the source region 153S, and the drain electrode 223d is ohmically bonded to the drain region 153D. The source electrode 223s and the drain electrode 223d are formed in the same process as the source electrode 221s and the drain electrode 221d in the first transistor region T1 (and the gate electrode 222g in the second transistor region T2), include the same materials as the materials included in the source electrode 221s and the drain electrode 221d, and each have a thickness that is substantially the same as the thicknesses of the source electrode 221s and the drain electrode 221d.

### (Method of Manufacturing Semiconductor Device 1)

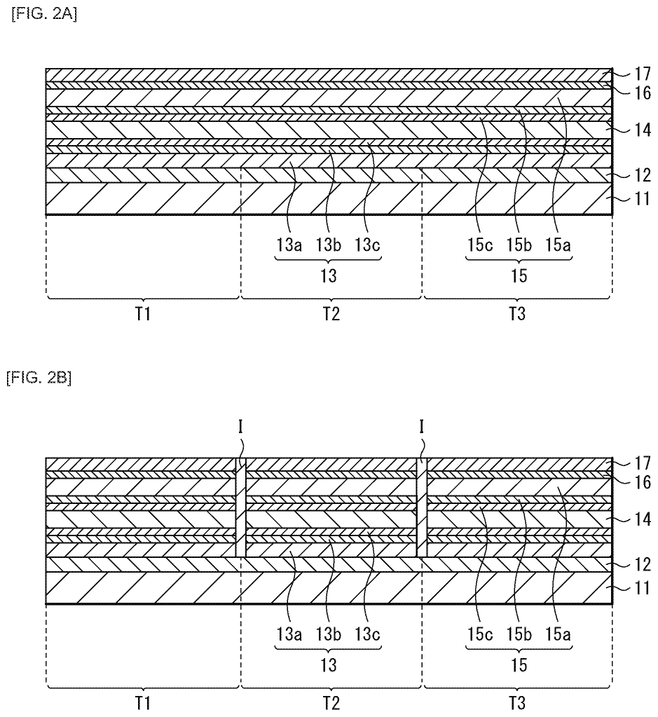

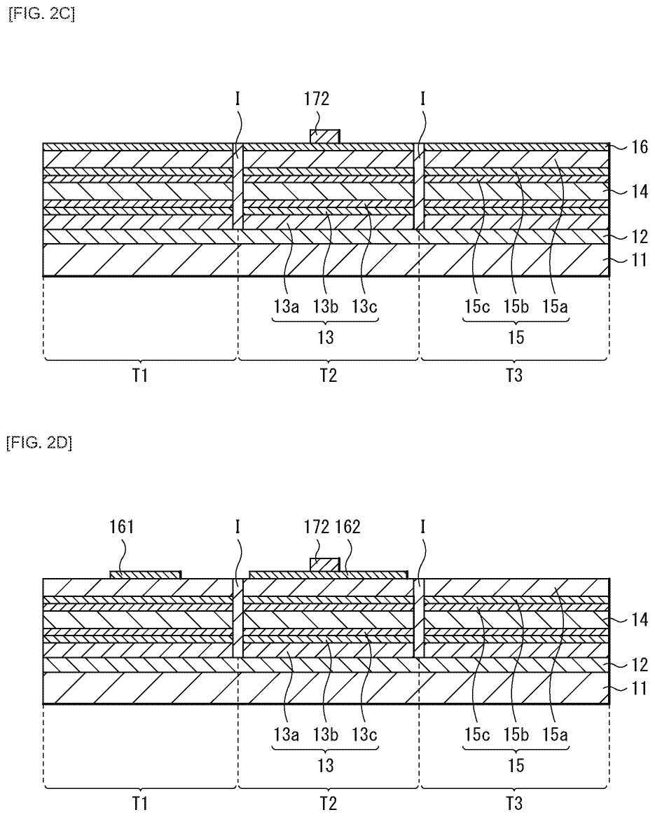

The semiconductor device 1 having the above configuration may be manufactured, for example, as follows (FIGS. 2A to 4C).

First, as illustrated in FIG. 2A, the buffer layer 12, the lower barrier layer 13, the channel layer 14, the upper barrier layer 15, a p-type semiconductor layer 16, and an n-type semiconductor layer 17 are formed in this order over the substrate 11, over the entire surface of the substrate 11. Specifically, for example, these are formed in the following manner.

First, on the substrate 11 including, for example, GaAs, the buffer layer 12 is formed by epitaxially growing an i-GaAs layer to which no impurity is added. Thereafter, on the buffer layer 12, the lower barrier layer 13 is formed by epitaxically growing an AlGaAs (Al_{0.2}Ga_{0.8}As mixed crystal) layer, for example. At this time, for example, the high-resistance region 13a including an i-AlGaAs layer to which no impurity is added, the carrier supply region 13b including an n-type AlGaAs layer to which silicon (Si) is added, and the high-resistance region 13c including an i-AlGaAs layer to which no impurity is added are sequentially epitaxially grown. Thus, the lower barrier layer 13 having the n-type carrier supply region 13b at the middle in the film thickness direction is formed.

Next, the channel layer 14 is formed on the lower barrier layer 13 by epitaxially growing, for example, an i-InGaAs layer to which no impurity is added.

Thereafter, on the channel layer 14, for example, an AlGaAs (Al_{0.2}Ga_{0.8}As mixed crystal) layer is epitaxically grown to form the upper barrier layer 15. At this time, for example, the high-resistance region 15c including an i-AlGaAs layer to which no impurity is added, the carrier supply region 15b including an n-type AlGaAs layer to which silicon (Si) is added, and the high-resistance region 15a including an n-type AlGaAs layer to which silicon (Si) is added are sequentially epitaxially grown. Thus, the upper barrier layer 15 having the n-type carrier supply region 15b at the middle in the film thickness direction is formed.

Subsequently, an AlGaAs layer to which carbon (C) is added as a p-type impurity, for example, is epitaxially grown on the upper barrier layer 15 to form the p-type semiconductor layer 16. Thereafter, on the p-type semiconductor layer 16, for example, the n-type semiconductor layer 17 is formed by epitaxially growing a GaAs layer to which silicon (Si) is added as an n-type impurity. The p-type semiconductor layer 16 is for forming the p-type impurity epitaxial layer 161 and the channel layer 162, and the n-type semiconductor layer 17 is for forming the n-type impurity epitaxial layer 172.

After the n-type semiconductor layer 17 is formed, the element separation regions I are formed as illustrated in FIG. 2B. The element separation regions I are each formed by, for example, ion implantation of boron (B). Thus, the first transistor region T1, the second transistor region T2, and the third transistor region T3 are formed.

After the element separation regions I are formed, the n-type semiconductor layer 17 is patterned to form the n-type impurity epitaxial layer 172 as illustrated in FIG. 2C. The n-type impurity epitaxial layer 172 is provided on the p-type semiconductor layer 16 and is disposed on a selective region in the second transistor region T2. The n-type semiconductor layer 17 is patterned by, for example, wet etching using a photo resist as a mask.

After the n-type impurity epitaxial layer 172 is formed, the p-type semiconductor layer 16 is patterned to form the p-type impurity epitaxial layer 161 and the channel layer 162, as illustrated in FIG. 2D. As described above, it is possible to form the p-type impurity epitaxial layer 161 in the first transistor region T1 and the channel layer 162 in the second transistor region T2 in the same process by patterning the p-type semiconductor layer 16. The p-type semiconductor layer 16 is patterned by, for example, wet etching using a photo resist as a mask. Instead of wet etching, dry etching may be used. The entire p-type semiconductor layer 16 in the third transistor region T3 may be removed, for example.

After the p-type impurity epitaxial layer 161 and the channel layer 162 are formed, the interlayer insulating film 21 is formed as illustrated in FIG. 3A. The interlayer insulating film 21 is formed on the upper barrier layer 15 to cover the n-type impurity epitaxial layer 172, the p-type impurity epitaxial layer 161, and the channel layer 162. The interlayer insulating film 21 is formed by, for example, forming a silicon nitride (Si₃N₄) film by a CVD (Chemical Vapor Deposition) method.

After the interlayer insulating film 21 is formed, openings 211g, 212s, 212d, and 213g are formed in the interlayer insulating film 21 as illustrated in FIG. 3B. The opening 211g is for forming the gate region 161G in the first transistor region T1 (FIG. 3C to be described later) and is formed so as to expose the central portion of the p-type impurity epitaxial layer 161. The openings 212s and 212d are for forming the source region 162S and the drain region 162D, respectively, in the second transistor region T2 (FIG. 3C to be described later), and are formed so as to sandwich the n-type impurity epitaxial layer 172 in a plan view. The openings 212s and 212d are formed so as to expose the surface of the n-type impurity epitaxial layer 172. The opening 213g is for forming the gate region 153G in the third transistor region T3 (FIG. 3C to be described later) and is formed so as to expose the surface of the high-resistance region 15a. The openings 211g, 212s, 212d, and 213g are formed by, for example, pattern-etching.

After the openings 211g, 212s, 212d, and 213g are formed in the interlayer insulating film 21, p-type impurities are introduced through the openings 211g, 212s, 212d, and 213g as illustrated in FIG. 3C. For example, zinc (Zn) is used as a p-type impurity and gas phase diffusion is performed using a zinc compound gas at about 600° C. A depth of introduction of the p-type impurity is greater than the thicknesses of the p-type impurity epitaxial layer 161 and the channel layer 162, and does not reach the carrier supply region 15b in the third transistor region T3. Thus, the gate regions 161G and 153G, the source region 162S, and the drain region 162D are formed in the same process. In the first transistor region T1, the low concentration regions 161L on the outer sides of the gate region 161G are self-aligned with the gate region 161G at the central portion of the p-type impurity epitaxial layer 161.

After the p-type impurities are introduced through the openings 211g, 212s, 212d, and 213g in the interlayer insulating film 21, the gate electrodes 221g and 223g, the source electrode 222s, and the drain electrode 222d are formed as illustrated in FIG. 4A. The gate electrode 221g is formed to fill the opening 211g, the source electrode 222s and the drain electrode 222d are formed to fill the openings 212s and 212d, respectively, and the gate electrode 223g is formed to fill the opening 213g. The gate electrodes 221g and 223g, the source electrode 222s, and the drain electrode 222d are formed, for example, by sequentially performing mask vapor deposition of titanium (Ti), platinum (Pt), and gold (Au). In this way, the gate electrodes 221g and 223g, the source electrode 222s, and the drain electrode 222d are formed in the same process.

Next, as illustrated in FIG. 4B, openings 211s, 211d, 213s, and 213d are formed in the interlayer insulating film 21. The openings 211s and 211d are for forming the source region 151S and the drain region 151D, respectively, in the first transistor region T1 (FIG. 4C to be described later), and are formed so as to sandwich the gate electrode 221g and the p-type impurity epitaxial layer 161 in a plan view. The openings 211s and 211d are formed so as to expose the surface of the high-resistance region 15a. The openings 213s and 213d are for forming the source region 153S and the drain region 153D, respectively, in the third transistor region T3 (FIG. 4C to be described later), and are formed so as to expose the surface of the high-resistance region 15a. The openings 211s, 211d, 213s, and 213d are formed, for example, by pattern etching.

After the openings 211s, 211d, 213s, and 213d are formed in the interlayer insulating film 21, an n-type ohmic metal is thermally diffused through the openings 211s, 211d, 213s, and 213d as illustrated in FIG. 4C. For example, 50 nm each of gold-germanium (Au—Ge), nickel (Ni), and gold (Au) are stacked in this order from the upper barrier layer 15 side, and are thermally diffused at a temperature of about 500° C. to form the source regions 151S and 153S and the drain regions 151D and 153D. After the introduction of the n-type ohmic contact metal diffusion layer, an opening 212g for exposing the surface of the n-type impurity epitaxial layer 172 is formed in the interlayer insulating film 21 (FIG. 4C).

Subsequently, the source electrodes 221s and 223s, the drain electrodes 221d and 223d, and the gate electrode 222g are formed (FIG. 1). The source electrodes 221s and 223s and the drain electrodes 221d and 223d are formed so as to fill the openings 211s, 211d, 213s, and 213d, respectively, and the gate electrode 222g is formed so as to fill the opening 212g. The gate electrode 222g, the source electrodes 221s and 223s, and the drain electrodes 221d and 223d are formed, for example, by stacking titanium (Ti), titanium nitride (TiN), titanium (Ti), and copper (Cu) in this order from the upper barrier layer 15 side, and alloying them with the underlying n-type ohmic contact metal diffusion layer (the source region 151S or the drain region 151D). The source electrode 221s and the drain electrode 221d each have a thickness of, for example, 300 nm. In this way, the source electrodes 221s and 223s, the drain electrodes 221d and 223d, and the gate electrode 222g are formed in the same process.

### (Workings and Effects of Semiconductor Device)

In the semiconductor device 1 according to the present embodiment, the substrate 11 is provided with the first transistor region T1, the second transistor region T2, and the third transistor region T3. Hereinafter, each of the first transistor region T1, the second transistor region T2, and the third transistor region T3 will be described.

### [First Transistor Region T1]

The first transistor region T1 on the substrate 11 is provided with the n-type FET including the channel layer 14 in which electrons travel. Over the channel layer 14, the upper barrier layer 15, the p-type impurity epitaxial layer 161, and the gate electrode 221g are provided in this order. That is, the first transistor region T1 is provided with the n-type FET having a depletion-type (normally-on type) pHEMT structure.

Here, the p-type impurity epitaxial layer 161 includes the gate region 161G on the central portion and the low concentration regions 161L provided on outer sides of the gate region 161G. The p-type electric charge amount of the entire low concentration regions 161L is smaller than the p-type electric charge amount of the gate region 161G; therefore, it is possible to spread a depletion layer between the channel layer 14 and the p-type impurity epitaxial layer 161, and to increase pressure resistance between the gate and the drain.

### [Second Transistor Region T2]

In the present embodiment, the second transistor region T2 on the substrate 11 is provided with the p-type FET including the channel layer 162 in which holes travel. Therefore, it is possible to form the n-type FET having a pHEMT structure over the substrate 11 in the first transistor region T1 and also to form the p-type FET over the substrate 11 in the second transistor region.

Further, it is possible to form the channel layer 162 in the same process as the p-type impurity epitaxial layer 161 in the first transistor region T1, and to form the source region 162S and the drain region 162D in the same process as the gate region 161G in the first transistor region T1. In addition, the n-type impurity epitaxial layer 172 is a protective layer of the underlying epitaxially stacked substrate. Therefore, it is possible to easily manufacture the p-type FET in the second transistor region T2 together with the n-type FET in the first transistor region T1.

Still further, in the first transistor region T1 and the second transistor region T2, the substrate 11, the buffer layer 12, the lower barrier layer 13, the channel layer 14, and the upper barrier layer 15 are commonly provided, and the channel layer 162 in the second transistor region T2 is provided in the same layer as the p-type impurity epitaxial layer 161 in the first transistor region T1. That is, the p-type FET in the second transistor region T2 is formed substantially without a step with the n-type FET in the first transistor region T1.

The p-type FET provided in the second transistor region T2 is able to perform any of a depletion-type operation and an enhancement-type (normally-off type) operation, for example, by changing channel concentrations of the channel layer 162 and the n-type impurity epitaxial layer 172.

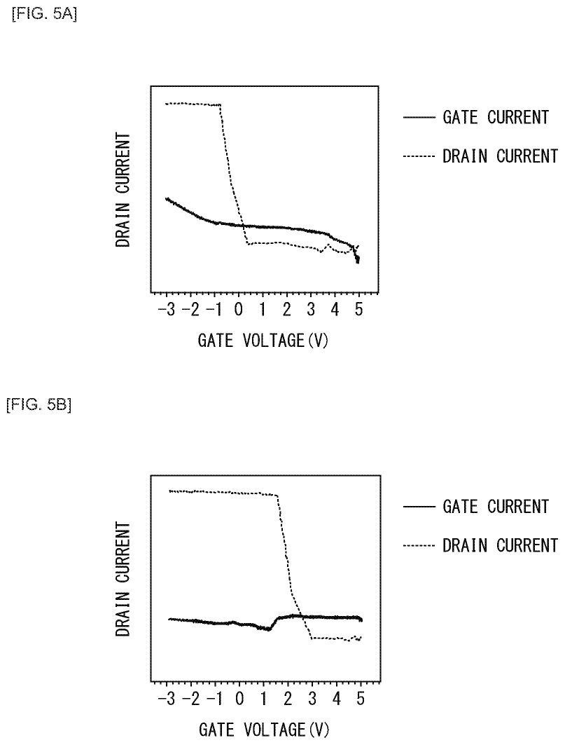

FIG. 5A and FIG. 5B each illustrates a simulation result of gate voltage (Vg)-drain current (Id) characteristics and gate voltage (Vg)-gate current (Ig) characteristics of the p-type FET formed in the second transistor region T2. FIG. 5A represents an enhancement-type p-type FET, and FIG. 5B represents a depletion-type p-type FET. In a case where a current of 1 kA is controlled with a gate length of 0.4 μm and a gate width of 1.0 μm, a threshold voltage of the enhancement type is about −0.5V and a threshold voltage of the depletion type is about +1.8 V.

### [Third Transistor Region T3]

The third transistor region T3 on the substrate 11 is provided with the n-type FET including the channel layer 14 in which electrons travel. The third transistor region T3 is not provided with a layer corresponding to the p-type impurity epitaxial layer 161 in the first transistor region T1, and the gate region 153G in the third transistor region T3 is formed deeper in the high-resistance region 15a than the gate region 161G in the first transistor region T1. As a result, it is possible to form an enhancement-type n-type FET in the third transistor region T3 while a depletion-type n-type FET is formed in the first transistor region T1.

Further, it is possible to form the n-type FET in the third transistor region T3 through the same process as the n-type FET in the first transistor region T1, except that the layer corresponding to the p-type impurity epitaxial layer 161 is not formed. Therefore, it is possible to easily manufacture the n-type FET in the third transistor region T3 together with the n-type FET in the first transistor region T1.

In addition, in the first transistor region T1 and the third transistor region T3, the substrate 11, the buffer layer 12, the lower barrier layer 13, the channel layer 14, and the upper barrier layer 15 are commonly provided. That is, the n-type FET in the third transistor region T3 is formed substantially without a step with the n-type FET in the first transistor region T1.

In the present embodiment, since the n-type FET of the first transistor region T1, the p-type FET of the second transistor region T2, and the n-type FET of the third transistor region T3 are formed substantially simultaneously as described above, it is possible to easily form these FETs.

Further, the first transistor region T1, the second transistor region T2, and the third transistor region T3 on the substrate 11 have many common structures, and there is almost no step between these regions. Hereinafter, workings and effects of such a semiconductor device 1 will be described.

As a method of forming an n-type FET and a p-type FET on a substrate, for example, a method using an ion-implantation technique may be considered (see, for example, Japanese Unexamined Patent Application Publication No. S61-150380 and Japanese Unexamined Patent Application Publication No. H01-204475). In this method, a p-type dopant and a n-type dopant are separately implanted on a substrate to form an n-channel forming region and a p-channel forming region. In this method, in order to activate the implanted dopant, it is necessary to perform high-temperature annealing at 800° C. or higher after the ion implantation. Since the heterojunction of pHEMT is formed by an epitaxial growth method of about 600° C., the high-temperature annealing at 800° C. or higher after the ion implantation may cause interdiffusion of compound composition elements and impurity elements at the heterojunction interface. That is, it becomes difficult to form a desired heterojunction.

In addition, in the epitaxial film forming process, a method of separately forming the n-type FET and the p-type FET may be considered (for example, see Japanese Unexamined Patent Application Publication No. H02-257669 and Japanese Unexamined Patent Application Publication No. H09-69611). The method is performed, for example, as follows. First, regarding one conductivity type, after forming a stack using an epitaxial growth method, a portion of the stack is removed by etching. Thereafter, a stack of the other conductivity type is formed on the removed portion of the stack. Such a method is complex and it is difficult to perform manufacturing. Further, since the regrown film is once exposed to the atmosphere, the film quality tends to be deteriorated.

A method is also conceivable in which both n-type FET and p-type FET are formed by sequential epitaxial growth (see, for example, Japanese Unexamined Patent Application Publication No. H10-313096 and Japanese Unexamined Patent Application Publication No. 2011-192952).

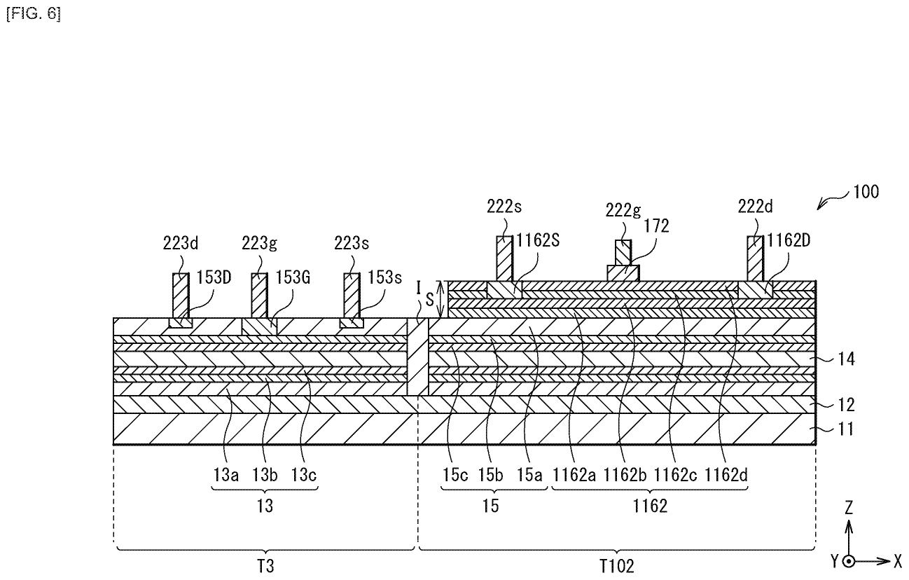

FIG. 6 illustrates a schematic cross-sectional configuration of a main part of a semiconductor device (a semiconductor device 100) formed by such a method. The semiconductor device 100 is a semiconductor device according to a comparative example. In the semiconductor device 100, a second transistor region (a second transistor region T102) on the substrate 11 is provided with a p-type FET, and the third transistor region T3 is provided with an n-type FET. The semiconductor device 100 includes the substrate 11, the buffer layer 12, the lower barrier layer 13, the channel layer 14, and the upper barrier layer 15, commonly in the second transistor region 102 and the third transistor region 3. A stepped portion (a stepped portion 1162) of the upper barrier layer 15 is provided only in the second transistor region T102. The stepped portion 1162 includes, for example, a cap layer 1162a, a buffer layer 1162b, a channel layer 1162c, and a gate leakage preventing layer 1163d in this order from the upper barrier layer 15 side. In the semiconductor device 100, the cap layer 1162a, the buffer layer 1162b, the channel layer 1162c, and the gate leakage preventing layer 1163d in the third transistor region T3 are removed by etching. Therefore, a step S attributed to the stepped portion 1162 is generated between the second transistor region T102 and the third transistor region T103. The step S is, for example, about 0.5 μm to 1 μm.

The step S is steep, and in particular, tends to cause a defect in the miniaturized device. For example, in a wiring process for coupling the n-type FET and the p-type FET, a processing residue is accumulated in the step S, and short-circuit between the wires may occur due to the processing residue. Further, there is also an issue that it becomes difficult to perform a lithography process.

In contrast to these methods, in the semiconductor device 1, it is possible to substantially simultaneously form the n-type FET in the first transistor region T1, the p-type FET in the second transistor region T2, and the n-type FET in the third transistor region T3, and to simplify the manufacturing process.

Further, the first transistor region T1, the second transistor region T2, and the third transistor region T3 on substrate 11 have many common structures, and there is almost no step (step S in FIG. 6) between these regions. Therefore, it is possible to suppress the occurrence of defects caused by the step.

Such a semiconductor device 1 is suitably applicable to a power supply circuit such as a DC/DC converter, because the first transistor region T1 that is able to function as a power semiconductor element, the second transistor region T2 and the third transistor region T3 each including a complementary semiconductor element are formed on the same substrate (substrate 11). The reason therefor will be described below.

The DC/DC converter includes, for example, a high-side switch, a low-side switch, and a gate drive circuit and a peripheral circuit for driving the high-side switch and the low-side switch. A power semiconductor element included in the high-side switch and the low-side switch, and the gate drive circuit and the peripheral circuit, for example, are coupled to each other using wire bonding or a wiring line of a printed substrate. Due to such coupling methods, parasitic inductance tends to occur in the DC/DC converter. The parasitic inductance, for example, may cause a delay in the switch operation with increase in a loop inductance component. Further, in a recovery process of the delay of the switch operation, there is a possibility that fluctuations in the potential of the power supply and the ground may occur.

In contrast, in the semiconductor device 1, on the same substrate (substrate 11), there are provided: the first transistor region T1 that is able to function as a power semiconductor element; and the second transistor region T2 and the third transistor region T3 that are complementary and able to function as the gate drive circuit and the peripheral circuit. Therefore, for example, it is possible to integrate the power supply circuitry such as the DC/DC converter on one chip. Thus, it is possible to suppress the occurrence of parasitic inductance due to the above coupling method. Further, by integrating the power supply circuit such as the DC/DC converter on one chip, it is also possible to achieve miniaturization.

Still further, it is possible to easily manufacture the semiconductor device 1 as described above, thereby reducing costs. In addition, in the semiconductor device 1, it is possible to suppress occurrence of a defect caused by a step on the surface of the device; thus, that it is possible to improve the quality and the yield.

As described above, in the present embodiment, the channel layer 14 is formed over the substrate 11 in the first transistor region T1 and the channel layer 162 is formed over the substrate 11 in the second transistor region T2; therefore, it is possible to form the n-type FET over the substrate 11 in the first transistor region T1 and to form the p-type FET over the substrate 11 in the second transistor region T2. Thus, it is possible to provide the p-type FET and the n-type FET on one substrate (substrate 11).

Hereinafter, a modification example of the above embodiment will be described; however, in the following description, the same components as those of the above embodiment will be denoted by the same reference numerals, and description thereof will be omitted as appropriate.

### Modification Example

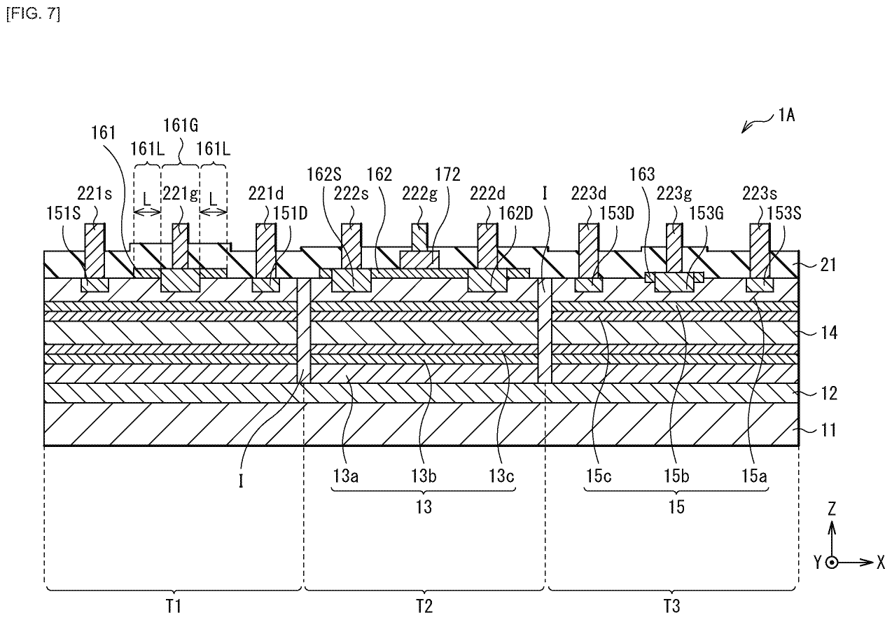

FIG. 7 schematically illustrates a cross-sectional configuration of a main part of a semiconductor device (a semiconductor device 1A) according to a modification example of embodiment. In the semiconductor device 1A, the third transistor region T3 on the substrate 11 is also provided with a p-type impurity epitaxial layer (a p-type impurity epitaxial layer 163). Except for this point, the semiconductor device 1A includes a configuration similar to that of the semiconductor device 1, and its workings and effects are the same as those of the semiconductor device 1.

The p-type impurity epitaxial layer 163 (a third impurity epitaxial layer) is formed in the same process as the p-type impurity epitaxial layer 161 in the first transistor region T1 (and the channel layer 162 in the second transistor region T2), includes the same materials as the p-type impurity epitaxial layer 161, and has a thickness that is substantially the same as the thickness of the p-type impurity epitaxial layer 161. That is, the p-type impurity epitaxial layer 163 is provided in the same layer as the p-type impurity epitaxial layer 161 and the channel layer 162. The p-type impurity epitaxial layer 163 is provided in a selective region on the upper barrier layer 15 (the high-resistance region 15a) and is disposed between the upper barrier layer 15 and the gate electrode 223g. The p-type impurity epitaxial layer 163 opposes the channel layer 14 with the upper barrier layer 15 interposed therebetween.

The gate region 153G in the third transistor region T3 is provided from a surface of the p-type impurity epitaxial layer 163 (a surface on the gate electrode 223g side) into a portion in the thickness direction of the high-resistance region 15a. A distance between the gate region 153G and the channel layer 14 is substantially the same as a distance between the gate region 161G and the channel layer 14 in the first transistor region T1.

In the semiconductor device 1A according to the present modification example, the channel layer 14 is formed over the substrate 11 in the first transistor region T1 and the channel layer 162 is formed over the substrate 11 in the second transistor region T2, similarly to the semiconductor device 1; therefore, it is possible to form the n-type FET over the substrate 11 in the first transistor region T1 and the p-type FET over the substrate 11 in the second transistor region T2. Thus, it is possible to provide the p-type FET and the n-type FET on one substrate (substrate 11).

Further, since the p-type impurity epitaxial layer 163 corresponding to the p-type impurity epitaxial layer 161 (the first transistor region T1) is provided in the third transistor region T3, it is possible to form the depletion-type n-type FET in each of the first transistor region T1 and the third transistor region T3.

Although the present technology has been described with reference to the embodiment and the modification example, the present technology is not limited to the embodiment and the like described above, and various modifications can be made. For example, the components, the arrangement, the number, and the like of the semiconductor devices 1 and 1A described in the above embodiment and the like are merely examples, and the semiconductor devices 1 and 1A do not necessarily include all the components, and may further include other components.

In addition, the material and the thickness of each layer described in the above embodiment and the like, or the film forming method, the film forming condition, and the like are not limited, and may be other materials and thicknesses, or may be other film forming methods and film forming conditions.

It is to be noted that the effects described herein are mere examples, are not limited to those described herein, and may include any effects other than those described herein.

It is to be noted that the present technology may have the following configurations.

(1)

A semiconductor device including:

a substrate in which a first transistor region and a second transistor region are provided; a first channel layer in which a carrier of a first conductivity type travels, the first channel layer being provided over the substrate in the first transistor region and including a compound semiconductor;

a first impurity epitaxial layer of a second conductivity type that is provided over the substrate with the first channel layer interposed therebetween, is disposed in a first gate region in a central portion and outside the first gate region, and has a low concentration region in which an electric charge amount per unit length is small as compared to the first gate region; and

a second channel layer in which a carrier of the second conductivity type travels, the second channel layer being provided over the substrate in the second transistor region and including a compound semiconductor.

(2)

The semiconductor device according to (1), in which the first gate region and the low concentration region are provided continuously.

(3)

The semiconductor device according to (1) or (2), in which the second channel layer includes a material that is identical to a material included in the first impurity epitaxial layer.

(4)

The semiconductor device according to any one of (1) to (3), in which the second channel layer is provided in a layer that is identical to the first impurity epitaxial layer.

(5)

The semiconductor device according to any one of (1) to (4), further including a second impurity epitaxial layer of the first conductivity type provided in a selective region on the second channel layer.

(6)

The semiconductor device according to any one of (1) to (5), in which the substrate is further provided with a third transistor region, and the first channel layer is also provided over the substrate in the third transistor region.

(7)

The semiconductor device according to (6), in which, in the third transistor region, the carrier of the first conductivity type travels in the first channel layer.

(8)

The semiconductor device according to (6) or (7), further including

a lower barrier layer provided over the substrate across the first transistor region, the second transistor region, and the third transistor region, the lower barrier layer including a compound semiconductor; and

an upper barrier layer that is opposed to the lower barrier layer with the first channel layer interposed therebetween, the upper barrier layer being provided between the first channel layer and the first impurity epitaxial layer.

(9)

The semiconductor device according to (8), in which the first gate region is provided from the first impurity epitaxial layer into a portion in a thickness direction of the upper barrier layer.

(10)

The semiconductor device according to (9), further including a second gate region over the substrate in the third transistor region, the second gate region having an impurity of the second conductivity type diffused in a portion in a thickness direction of the upper barrier layer.

(11)

The semiconductor device according to (10), in which a distance between the second gate region and the first channel layer is shorter than a distance between the first gate region and the first channel layer.

(12)

The semiconductor device according to (9), further including

a third impurity epitaxial layer of the second conductivity type provided over the substrate in the third transistor region, the third impurity epitaxial layer being opposed to the first channel layer with the upper barrier layer interposed therebetween.

(13)

A method of manufacturing a semiconductor device, the method including:

forming, over a substrate in a first transistor region, a first channel layer in which a carrier of a first conductivity type is allowed to travel, the first channel layer including a compound semiconductor;

forming a first impurity epitaxial layer of a second conductivity type at a position opposed to the substrate with the first channel layer interposed therebetween, and forming, over the substrate in a second transistor region, a second channel layer in which a carrier of the second conductivity type is allowed to travel, the second channel layer including a compound semiconductor; and

forming a first gate region in a central portion of the first impurity epitaxial layer and a low concentration region outside the first gate region, by diffusing selectively an impurity of the second conductivity type in the central portion of the first impurity epitaxial layer.

(14)

The method of manufacturing the semiconductor device according to (13), in which the first impurity epitaxial layer and the second channel layer are formed in a single process.

(15)

The method of manufacturing the semiconductor device according to (13) or (14), the method further including:

forming a source region and a drain region by diffusing an impurity of the second conductivity type in portions of the second channel layer; and

forming the source region and the drain region in a single process with the first gate region.

(16)

The method of manufacturing the semiconductor device according to any one of (13) to (15), in which the first channel layer is formed over the substrate across the first transistor region and the third transistor region.

(17)

The method of manufacturing the semiconductor device according to (16), the method further including:

forming a second gate region over the substrate in the third transistor region, the second gate region being opposed to the substrate with the first channel layer interposed therebetween; and

forming the second gate region and the first gate region in a single process.

This application claims the benefit of Japanese Priority Patent Application JP2018-150547 filed with the Japan Patent Office on Aug. 9, 2018, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A semiconductor device comprising:
a substrate in which a first transistor region and a second transistor region are provided;
a first channel layer in which a carrier of a first conductivity type travels, the first channel layer being provided over the substrate in the first transistor region and including a compound semiconductor;
a first impurity epitaxial layer of a second conductivity type that is provided over the substrate with the first channel layer interposed therebetween, is disposed in a first gate region in a central portion and outside the first gate region, and has a low concentration region in which an electric charge amount per unit length is small as compared to the first gate region; and
a second channel layer in which a carrier of the second conductivity type travels, the second channel layer being provided over the substrate in the second transistor region and including a compound semiconductor.

2. The semiconductor device according to claim 1, wherein the first gate region and the low concentration region are provided continuously.

3. The semiconductor device according to claim 1, wherein the second channel layer includes a material that is identical to a material included in the first impurity epitaxial layer.

4. The semiconductor device according to claim 1, wherein the second channel layer is provided in a layer that is identical to the first impurity epitaxial layer.

5. The semiconductor device according to claim 1, further comprising
a second impurity epitaxial layer of the first conductivity type provided in a selective region on the second channel layer.

6. The semiconductor device according to claim 1, wherein
the substrate is further provided with a third transistor region, and
the first channel layer is also provided over the substrate in the third transistor region.

7. The semiconductor device according to claim 6, wherein, in the third transistor region, the carrier of the first conductivity type travels in the first channel layer.

8. The semiconductor device according to claim 6, further comprising
a lower barrier layer provided over the substrate across the first transistor region, the second transistor region, and the third transistor region, the lower barrier layer including a compound semiconductor; and
an upper barrier layer that is opposed to the lower barrier layer with the first channel layer interposed therebetween, the upper barrier layer being provided between the first channel layer and the first impurity epitaxial layer.

9. The semiconductor device according to claim 8, wherein the first gate region is provided from the first impurity epitaxial layer into a portion in a thickness direction of the upper barrier layer.

10. The semiconductor device according to claim 9, further comprising
a second gate region over the substrate in the third transistor region, the second gate region having an impurity of the second conductivity type diffused in a portion in a thickness direction of the upper barrier layer.

11. The semiconductor device according to claim 10, wherein a distance between the second gate region and the first channel layer is shorter than a distance between the first gate region and the first channel layer.

12. The semiconductor device according to claim 9, further comprising
a third impurity epitaxial layer of the second conductivity type provided over the substrate in the third transistor region, the third impurity epitaxial layer being opposed to the first channel layer with the upper barrier layer interposed therebetween.

13. A method of manufacturing a semiconductor device, the method comprising:
forming, over a substrate in a first transistor region, a first channel layer in which a carrier of a first conductivity type is allowed to travel, the first channel layer including a compound semiconductor;
forming a first impurity epitaxial layer of a second conductivity type at a position opposed to the substrate with the first channel layer interposed therebetween, and forming, over the substrate in a second transistor region, a second channel layer in which a carrier of the second conductivity type is allowed to travel, the second channel layer including a compound semiconductor; and
forming a first gate region in a central portion of the first impurity epitaxial layer and a low concentration region outside the first gate region, by diffusing selectively an impurity of the second conductivity type in the central portion of the first impurity epitaxial layer.

14. The method of manufacturing the semiconductor device according to claim 13, wherein the first impurity epitaxial layer and the second channel layer are formed in a single process.

15. The method of manufacturing the semiconductor device according to claim 13, the method further comprising:
forming a source region and a drain region by diffusing an impurity of the second conductivity type in portions of the second channel layer; and
forming the source region and the drain region in a single process with the first gate region.

16. The method of manufacturing the semiconductor device according to claim 13, wherein the first channel layer is formed over the substrate across the first transistor region and the third transistor region.

17. The method of manufacturing the semiconductor device according to claim 16, the method further comprising:
forming a second gate region over the substrate in the third transistor region, the second gate region being opposed to the substrate with the first channel layer interposed therebetween; and
forming the second gate region and the first gate region in a single process.
